(19) United States
(12) Patent Application Publication
(10) Pub. No.: US 2025/0212456 A1
(43) Pub. Date: Jun. 26, 2025

(54) LOW LEAKAGE CURRENT MOS TRANSISTOR

(71) Applicant: COMMISSARIAT A L'ENERGIE ATOMIQUE ET AUX ENERGIES ALTERNATIVES, PARIS (FR)

(72) Inventors: Laurent BRUNET, GRENOBLE CEDEX (FR); Joris LACORD, GRENOBLE CEDEX (FR)

(21) Appl. No.: 18/990,859

(22) Filed: Dec. 20, 2024

(30) Foreign Application Priority Data
Dec. 22, 2023 (FR) 2315149

(51) Int. Cl. H10D 30/67; H10D 30/01

(52) U.S. Cl. CPC H10D 30/6706; H10D 30/0312; H10D 30/6739; H10D 30/6734; H10D 30/6736

(57) ABSTRACT

One aspect of the invention relates to a field effect transistor (3) comprising:
a channel region (11);
a source region (12) and a drain region (13);
a gate structure (14) comprising:
   a gate dielectric layer (14b);
   a gate electrode (14a) with a first work function (W₁); and
   a lateral gate conductor (14c) disposed at least against the flank of the gate electrode (14a) located on the side of the drain region (13), the lateral gate conductor (14c) extending to the gate dielectric layer (14b) in direct contact with the gate electrode (14a) and having a second work function (W₂);
      the second work function (W₂) being:
strictly greater than the first work function (W₁) when the transistor is of type p;
strictly lower than the first work function (W₁) when the transistor is of type n.

### TECHNICAL FIELD OF THE INVENTION

The technical field of the invention is that of Metal Oxide Semiconductor Field Effect Transistors (MOSFETs), especially those manufactured from a substrate comprising a buried insulating layer, typically a Silicon On Insulator (SOI) type substrate. The present invention more particularly relates to a field effect transistor comprising a gate structure configured to decrease the Gate Induced Drain Leakage (GIDL) current.

### TECHNOLOGICAL BACKGROUND OF THE INVENTION

A Silicon On Insulator (SOI) substrate successively comprises a silicon support layer, an electrically insulating so-called Buried Oxide Layer (BOX layer) and a thin film of single-crystal silicon, also called the active layer. The active layer is thus named because it is to receive active components, typically metal oxide semiconductor field effect transistors (MOSFETs). The conduction channel of the MOSFETs is formed in the active layer. The SOI substrate especially makes it possible to manufacture Fully Depleted SOI (FDSOI) or Partially Depleted SOI (PDSOI) transistors.

FIG. 1 is a schematic cross-section view of an SOI transistor 1. The SOI transistor 1 comprises a channel region 11, a source region 12 and a drain region 13, all three formed in the silicon thin film of the SOI substrate. The channel region 11 is disposed between the source region 12 and the drain region 13. The silicon thin film has a gate electrode 14a thereabove, disposed facing the channel region 11. The gate electrode 14a is separated from the channel region 11 by a gate dielectric layer 14b.

The SOI transistor 1 further comprises a doped silicon region 15 called the “well”, a part 15′ of which called the “ground plane” or “back gate” is located under the electrically insulating layer 16 of the SOI substrate.

The back gate 15′ acts as a second gate. By varying the electrical potential of the back gate 15′, separated from the channel region 11 by the electrically insulating layer 16, it is possible to (dynamically) modulate the threshold voltage of the SOI transistor 1 and consequently its on-state resistance (RON).

The SOI transistor 1 can be an n-channel transistor, also called an nFET transistor, or a p-channel transistor, also called a pFET transistor. In an nFET transistor, the source and drain regions 12-13 are n-type doped and the channel region 11 is p-type doped. Conversely, in a pFET transistor, the source and drain regions 12-13 are p-type doped and the channel region 11 is n-type doped.

Like most MOSFETs formed on a bulk silicon substrate, the SOI transistor 1 suffers in the off state from a leakage current called gate induced drain leakage (GIDL) current.

The GIDL current results from the generation of electron-hole pairs in a depletion zone that forms at the surface of the drain region 13, where the gate electrode 14a overlaps the drain region 13. It occurs for gate-source voltage Vas values being negative in the case of an nFET and positive in the case of a pFET.

FIG. 2 represents a field effect transistor 2 designed to have a low GIDL current and described in patent application US2004/137689A1. This field effect transistor 2, of the nFET type, comprises:
a channel region 21, a source region 22, a drain region 23, all three formed in a bulk substrate;
a gate structure comprising:
   a so-called “central” gate electrode 24a of p-type doped polycrystalline silicon;
   a gate dielectric layer 24b separating the gate electrode 24a from the channel region 21;
   lateral gate extensions 25a of n-type doped polycrystalline silicon, disposed against flanks of the gate electrode 24a;
   an electrically insulating barrier layer 25b of silicon oxide separating the lateral gate extensions 25a from the substrate and the gate electrode 24a;
   metal spacers 26a of tungsten or tungsten nitride disposed on the lateral gate extensions 25a; and
   an electrically conductive barrier layer 26b separating the metal spacers 26a from the gate electrode 24a and the lateral gate extensions 25a; and
insulating spacers 27 disposed against flanks of the gate structure.

The thickness of the electrically insulating barrier layer 25b (of silicon oxide) is greater than the thickness of the gate dielectric layer 24b.

However, the field effect transistor 2 has significant stray capacitances and provides less control of short channel effects. In particular, the Drain-Induced Barrier Lowering (DIBL) effect is enhanced. In addition, manufacturing the transistor requires a very large number of technological steps.

### SUMMARY OF THE INVENTION

There is therefore a need for a field effect transistor with better electrical performance that can be manufactured more simply.

According to one aspect of the invention, this need tends to be satisfied by providing a field effect transistor comprising:
a source region and a drain region;
a channel region disposed between the source and drain regions;
a gate structure comprising:
   a gate dielectric layer disposed on the channel region;
   a gate electrode separated from the channel region by the gate dielectric layer and formed of a first conductive material having a first work function, the gate electrode comprising a first flank on the side of the source region and a second flank on the side of the drain region; and
   a lateral gate conductor disposed at least against the second flank of the gate electrode and extending to the gate dielectric layer in direct contact with the gate electrode, the lateral gate conductor being formed of a second conductive material having a second work function,
      wherein the second work function is:
strictly greater than the first work function when the transistor is of type p;
strictly lower than the first work function when the transistor is of type n.

The lateral gate conductor decreases the vertical electric field at least near the drain region when the transistor is biased at gate-source voltage Vas values being negative in the case of an nFET and positive in the case of a pFET, and hence the generation of electron-hole pairs by band-to-band tunneling which causes the GIDL current. Direct contact between the lateral gate conductor and the gate electrode avoids the appearance of new stray capacitances, ensures good control of short channel effects such as the DIBL effect and simplifies manufacture of the transistor.

In a preferred embodiment, the transistor further comprises an electrically insulating layer, on which the channel region and the source and drain regions are disposed.

According to a development of this preferred embodiment, the transistor further comprises a back gate separated from the channel region by the electrically insulating layer.

Further to the characteristics just discussed in the preceding paragraphs, the transistor according to the first aspect of the invention may have one or more complementary characteristics from among the following, considered individually or according to any technically possible combinations:
the second conductive material is a compound of semiconductor material and one or more metal elements, preferably a silicide;
the gate structure overlaps the source and drain regions;
the lateral gate conductor is disposed all around the gate electrode;
the transistor further comprises a spacer disposed on at least one flank of the gate structure and separated from the gate structure by a dielectric material layer;
the gate dielectric layer is of constant thickness;
the lateral gate conductor extends over the entire height of the gate electrode;
the second work function is:
   greater than or equal to 110% of the first work function when the transistor is p-type; and
   lower than or equal to 90% of the first work function when the transistor is n-type.

A second aspect of the invention relates to a method for manufacturing a field effect transistor comprising a source region, a drain region and a channel region disposed between the source and drain regions, the method comprising the following steps of:
forming a gate stack on a semiconducting layer, the gate stack comprising a gate dielectric layer disposed on the semiconducting layer and a gate electrode separated from the semiconducting layer by the gate dielectric layer, the gate electrode being formed of a doped semiconductor material having a first work function, the gate electrode having a first flank that has to be on the side of the source region and a second flank that has to be on the side of the drain region;
forming a sacrificial layer covering at least the second flank of the gate electrode;
forming a spacer against at least the second flank of the gate electrode, the spacer being separated from the gate electrode by the sacrificial layer;
partially etching the sacrificial layer so as to expose a part of the second flank of the gate electrode;
depositing a metal layer at least onto the exposed part of the second flank of the gate electrode;
performing annealing so as to react the metal with the doped semiconductor material of the gate electrode and transform a portion of the gate electrode into a lateral gate conductor extending to the gate dielectric layer in direct contact with a remaining portion of the gate electrode, the metal being selected so that the lateral gate conductor is formed of a second conductive material having a second work function, the second work function being:
   strictly greater than the first work function in the case of a p-type transistor;
   strictly lower than the first work function in the case of an n-type transistor.

In a preferred mode of implementation, the sacrificial layer is deposited onto the semiconducting layer, the flanks of the gate electrode and an upper face of the gate electrode, the spacer being further separated from the semiconducting layer by the sacrificial layer.

According to one development of this preferred mode of implementation, the step of partially etching the sacrificial layer advantageously comprises the following operations of:
etching an upper portion of the sacrificial layer disposed on the upper face of the gate electrode;
performing overetching of the sacrificial layer, so as to etch a portion of the sacrificial layer located between the gate electrode and the spacer.

Advantageously, the method further comprises, prior to the step of depositing the metal layer, a step of cleaning an exposed surface of the semiconducting layer, an upper face of the gate electrode and the exposed part of the second flank of the gate electrode, the cleaning step being carried out so as to continue etching the sacrificial layer between the gate electrode and the spacer.

Advantageously, the metal layer is further deposited onto an upper face of the gate electrode and onto exposed regions of the semiconducting layer located on either side of the gate stack and the spacer.

### BRIEF DESCRIPTION OF THE FIGURES

Other characteristics and advantages of the invention will appear clearly from the description given below, by way of indicating and in no way limiting purposes, with reference to the appended figures, among which:

FIG. 1 schematically represents an SOI transistor according to prior art;

FIG. 2 schematically represents a field effect transistor on a bulk silicon substrate according to prior art;

FIG. 3 schematically represents a preferred embodiment of a field effect transistor according to the first aspect of the invention, the transistor comprising lateral gate conductors;

FIG. 4 represents, as a function of the gate-source voltage Vas, the drain current ID of a pFET type transistor for several values of the work function W₂ of the lateral gate conductors;

FIG. 5 represents, as a function of the gate-source voltage Vas, the drain current ID of an nFET type transistor for several values of the work function W₂ of the lateral gate conductors; and

FIGS. 6A to 6G illustrate a preferred mode of implementation of the method for manufacturing a field effect transistor according to the second aspect of the invention.

For greater clarity, identical or similar elements are identified by identical reference signs throughout the figures.

### DETAILED DESCRIPTION

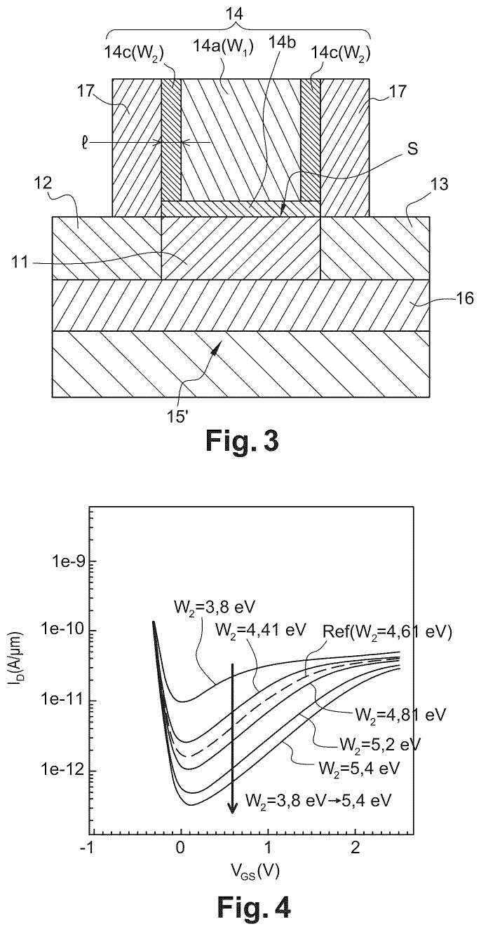

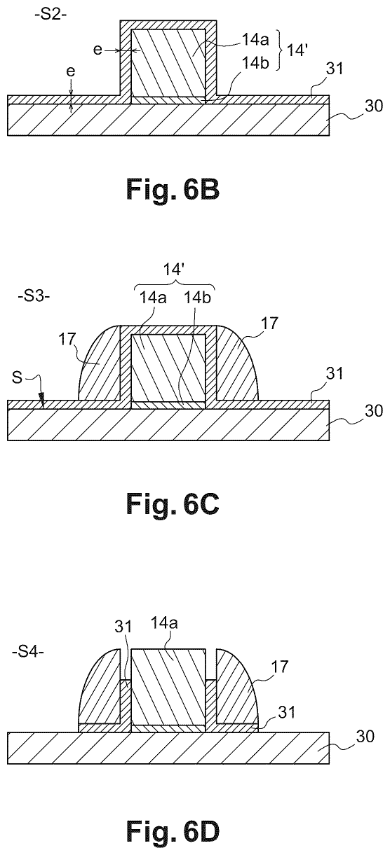

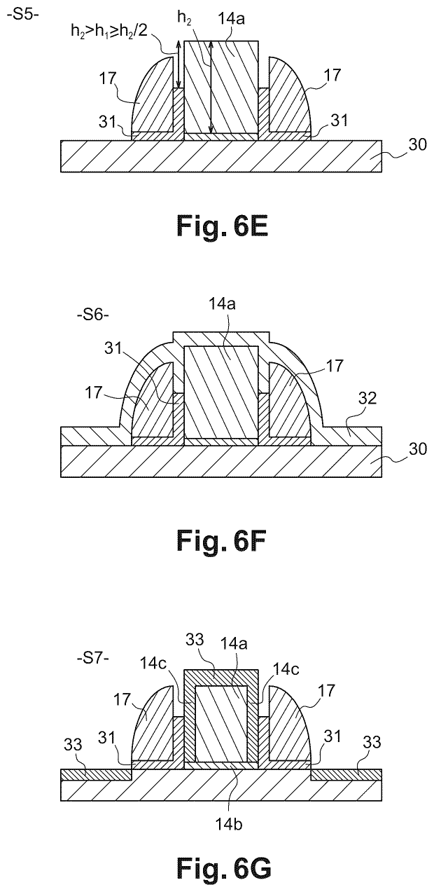

In the following description, the terms “front”, “back”, “upper”, “lower”, “top”, “bottom”, “horizontal”, “vertical”, “lateral”, etc. used to qualify the position or orientation of some elements refer to the orientation in FIGS. 3 and 6A to 6G. Furthermore, unless otherwise specified, the terms “approximately”, “substantially” and “in the order of” mean to within 10%.

FIG. 3 is a schematic cross-section view of a field effect (FET) transistor 3 according to a preferred embodiment of the invention.

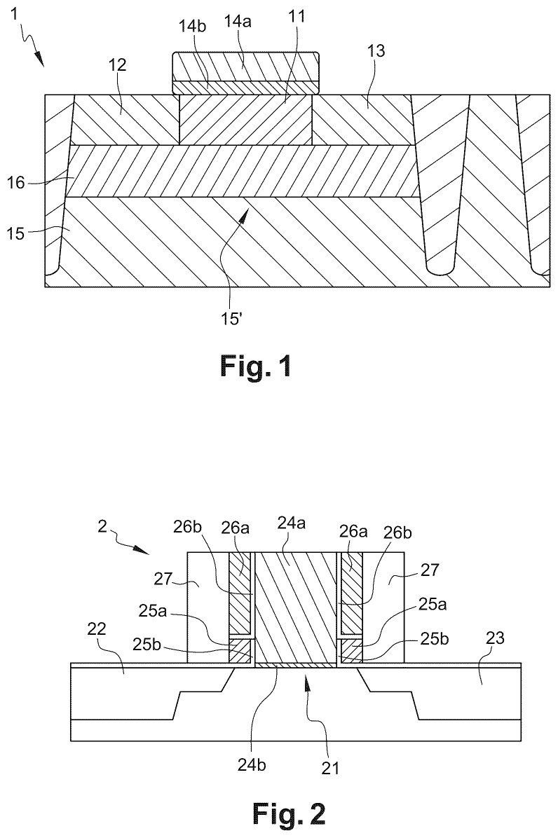

Like the transistor 1 illustrated in FIG. 1, the field effect transistor 3 (hereinafter referred to as transistor 3) comprises:
a channel region 11;
a source region 12 and a drain region 13 disposed on either side of the channel region 11;
a gate structure 14 disposed on the channel region 11;
an electrically insulating layer 16 on which the channel region 11, the source region 12 and the drain region 13 are disposed.

In this preferred embodiment, the transistor 3 is manufactured from a multilayer structure successively comprising a support layer, a so-called buried insulating layer and an active layer.

The support layer is preferably of a semiconductor material, for example silicon.

The buried insulating layer is preferably a buried oxide layer (or BOX layer), for example of silicon dioxide (SiO₂). Its thickness is between 5 nm and 145 nm, for example.

The active layer (also called thin layer, device layer or upper layer) is of a semiconductor material, for example silicon, germanium or a silicon-germanium alloy. Its thickness is between 3 nm and 100 nm, for example.

The multilayer structure can especially be a silicon-on-insulator (SOI) substrate. The transistor 3 is then referred to as an SOI transistor.

The channel region 11, the source region 12 and the drain region 13 are formed in the active layer of the multilayer structure. They rest on the insulating layer 16 (which corresponds to the buried insulating layer of the multilayer structure). These regions belong to the active zone of the transistor, which can be delimited laterally by electrical insulation trenches (not represented in FIG. 3, but visible in FIG. 1). The electrical insulation trenches extend through the active layer, the buried insulating layer and part of the support layer of the multilayer structure. The gate structure 14 is disposed on the active layer.

The channel region 11 can extend, in a direction perpendicular to a surface S of the multilayer structure, from the gate structure 14 to the insulating layer 16 and, in a plane parallel to this same surface S, from the source region 12 to the drain region 13. Thus the channel region 11 can have a thickness equal to that of the active layer. The source and drain regions 12-13 can also occupy the entire thickness of the active layer, as illustrated in FIG. 3.

The source and drain regions 12-13 are n-type doped in the case of an n-type field effect transistor (nFET) and p-type doped in the case of a p-type field effect transistor (pFET). Each of the source and drain regions 12-13 comprises a high-doped region, that is, a region whose concentration of doping impurities (of donor type in an nFET and of acceptor type in a pFET) is greater than or equal to 10¹⁸ cm⁻³, for example equal to 10²⁰ cm⁻³.

Each of the source and drain regions 12-13 may further comprise a low-doped region, commonly called an LDD (Low Doped Drain) extension, located between the channel region 11 and the high-doped region. The concentration of doping impurities in the LDD extensions is strictly lower than the concentration of doping impurities in the high-doped regions. For example, it is equal to 10¹⁹ cm⁻³ when the concentration of doping impurities in the high-doped regions is equal to 10²⁰ cm⁻³.

The gate structure 14 comprises a gate electrode 14a and a gate dielectric layer 14b separating the gate electrode 14a from the channel region 11. The transistor 3 is therefore a MOSFET. The gate electrode 14a is formed of a first electrically conductive material having a first work function W₁. This first conductive material may be a metal material such as titanium nitride (TiN) or tungsten (W), or doped polycrystalline silicon (equivalent to a metal in the meaning of the designation MOS). The gate dielectric layer 14b may be of silicon dioxide (SiO₂) or of a dielectric material having a higher dielectric constant than that of silicon dioxide (so-called “high-k” material). It can also comprise several sub-layers formed of different dielectric materials.

A feature of the transistor 3 is that the gate structure 14 further comprises a lateral gate conductor 14c disposed against at least one of the flanks (or lateral surfaces) of the gate electrode 14a. This lateral gate conductor 14c, also called lateral gate extension, preferably extends over the entire height of the gate electrode 14a. It is formed of a second electrically conductive material having a second work function W₂ different from the first work function W₁. The flank against which the lateral gate conductor 14c rests is located on the side of the drain region 13.

The lateral gate conductor 14c is preferably annular in shape and disposed around the gate electrode 14a. It is then disposed against all the flanks of the gate electrode 14a. Alternatively, the gate structure 14 can comprise two distinct lateral gate conductors 14c disposed against the two opposite flanks of the gate electrode 14a located on the side of the source region 12 and on the side of the drain region 13.

The second conductive material (and therefore the second work function W₂) is selected so as to reduce the vertical electric field in proximity to at least the drain region 13, and preferably in proximity to the source and drain regions 12-13, when the transistor 3 is biased at gate-source voltage V_{GS} values being negative in the case of an nFET and positive in the case of a pFET. Thus the generation of electron-hole pairs by band-to-band tunneling, which causes the GIDL current, is decreased.

The gate structure 14 comprising the lateral gate conductor (or lateral gate conductors) 14c may overlap the source and drain regions 12-13, that is, partially cover them. The effect of decreasing the GIDL current is then particularly strong.

The second conductive material is preferably a compound of semiconductor material and one or more metal elements, such as a silicide (compound of silicon and one or more metal elements). Alternatively, the second conductive material may be a metal material (that is, comprising one or more metals) or doped polycrystalline silicon.

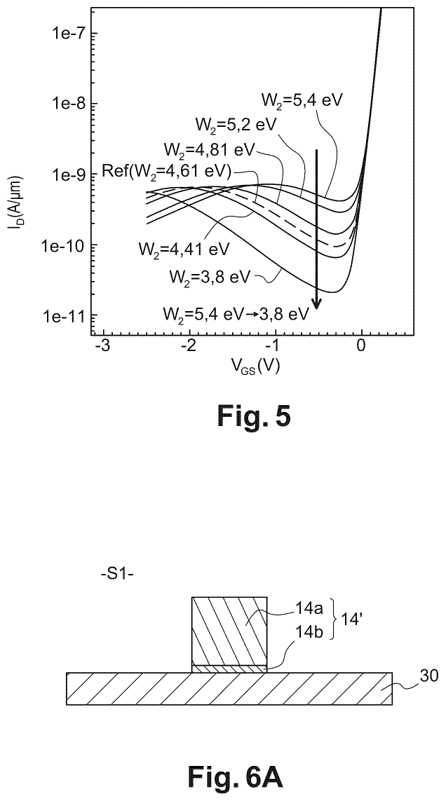

FIGS. 4 and 5 show digital simulation results for two examples of transistor 3 according to FIG. 3, a pFET and an nFET respectively. For each transistor, only the second work function W₂ of the lateral gate conductor 14c varies between the different digital simulations. The first work function W₁ of the gate electrode 14a is invariable and, in these simulations, equal to 4.61 eV (typical value for a “midgap” gate metal such as TiN and W). The reference simulation denoted as “Ref”, in which the second work function W₂ is equal to the first work function W₁(W₂=W₍₁₎=4.61 eV), corresponds to a transistor comprising a lateral gate conductor formed of the same material as the gate electrode 14a (that is, the equivalent of a transistor according to FIG. 1 comprising only the gate electrode 14a).

FIG. 4 represents the course of the drain current I_{D} of the pFET as a function of the gate-source voltage V_{GS} for different values of the second work function W₂ (ranging from 3.8 eV to 5.4 eV).

This figure shows that the drain current I_{D} at a positive voltage V_{GS} (in other words, the drain current of the pFET in the off state) decreases as the second work function W₂ increases and becomes lower than that of the reference transistor (“Ref” curve) when the second work function W₂ exceeds the value of the first work function W₁.

In other words, when the transistor 3 is of the pFET type, a second work function W₍₂₎ strictly greater than the first work function W₁ enables the GIDL current to be decreased.

By way of example, when the first conductive material (gate electrode 14a) is selected from titanium nitride (TiN)(W₁≈4.6 eV), tungsten (W) (W₁≈4.7 eV) and n-doped polycrystalline silicon (W₁≈4.0 eV), the second conductive material is advantageously selected from nickel silicides (4.6 eV≤W₂≤4.8 eV) and platinum silicides (5.16 eV≤W₂5.25 eV).

Similarly, FIG. 5 represents the course of the drain current I_{D} of the nFET as a function of the gate-source voltage V_{GS} for different values of the second work function W₂ (ranging from 3.8 eV to 5.4 eV).

This figure shows that the drain current I_{D} at a negative voltage V_{GS} (in other words the drain current of the nFET in the off state) decreases as the second work function W₂ decreases and becomes lower than that of the reference transistor (“Ref” curve) when the second work function W₂ becomes strictly lower than the first work function W₁.

Thus, when the transistor 3 is of the nFET type, a second work function W₍₂₎ strictly lower than the first work function Wi enables the GIDL current to be decreased.

By way of example, when the first conductive material (gate electrode 14a) is selected from titanium nitride (TiN)(W₁=4.6 eV), tungsten (W)(W₁≈4.7 eV) and p-doped polycrystalline silicon (W₁≈5.2 eV), the second conductive material is advantageously selected from titanium silicides (for example, W₂≈4.0 eV for TiSi₂) and tantalum silicides (ex. W₂≈4.2 eV for TaSi₂).

In order to obtain a significant decrease in the GIDL current, the second work function W₂ is advantageously:
greater than or equal to 110% of the first work function W₁ when the transistor is of the pFET type; and
lower than or equal to 90% of the first work function W₁ when the transistor is of the nFET type.

As illustrated in FIG. 3, the lateral gate conductor 14c extends to the gate dielectric layer 14b, in direct contact with the gate electrode 14a. In other words, there is therefore no intermediate layer (such as the electrically insulating barrier layer 25b in the transistor 2 of FIG. 2) between the lateral gate conductor 14c and the gate electrode 14a. The stray capacitances and other figures of merit of the transistor 3, such as the leakage current due to the DIBL effect, are therefore unaffected.

The lateral gate conductor 14c has a cross-section of width I which can be between 1 nm and 30 nm, for example equal to 10 nm or 20 nm. The width I of the lateral gate conductor 14c is measured in parallel to the surface S of the multilayer structure in the section plane of FIG. 3 (in other words along the same direction as the distance between the source and drain regions 12-13). Further digital simulations have shown that the width I of the lateral gate conductor 14c has a negligible impact on the current-voltage characteristic ID-V_{GS} of the transistor 3, and hence on the GIDL current.

Under the gate electrode 14a and the lateral gate conductor 14c, the gate dielectric layer 14b advantageously has a constant thickness, from one flank of the gate structure 14 to the other (or from the source region 12 to the drain region 13). The thickness of the gate dielectric layer 14b is, for example, between 2 nm and 20 nm.

The transistor 3 may also comprise a back gate 15′ separated from the channel region 11 by the insulating layer 16. The back gate 15′, also called the “ground plane”, is located under the insulating layer 16, facing the channel region 11. It acts as a second gate. By varying the electrical potential of the back gate 15′, it is possible to (dynamically) modulate the threshold voltage of the transistor 3 and consequently its on-state resistance (RON).

The back gate 15′ is formed of a doped semiconductor material. It preferably belongs to a doped semiconducting region called a well, extending beyond the active region of the transistor 3 (that is, beyond the electrical insulation trenches; see FIG. 1).

This well can be formed by implanting doping impurities into the support layer of the multilayer structure. The well can be n-type or p-type doped. The back gate 15′ may have a higher concentration of doping impurities than the remaining part of the well.

Finally, the transistor 3 may comprise a spacer 17 disposed against one or more flanks of the gate structure 14, and preferably all around the gate structure 14. This spacer 17 may be in direct contact with the gate dielectric layer 14b and the lateral gate conductor 14c, and preferably in direct contact with the source and drain regions 12-13. It is formed of a dielectric material such as silicon nitride (SiN). Alternatively, it can be separated from the lateral gate conductor 14c and the source and drain regions 12-13 by a dielectric material layer.

In an alternative embodiment not represented by the figures, the transistor 3 is manufactured from a bulk semiconductor substrate, for example of silicon, germanium or a silicon-germanium alloy. The transistor 3 then differs from that represented by FIG. 3 essentially in that it is devoid of an insulating layer 16 and a back gate 15′. The channel region 11, the source region 12 and the drain region 13 are formed in the bulk semiconductor substrate.

The GIDL current of a MOSFET transistor on a bulk substrate is also decreased by the use of the lateral gate conductor 14c having a different work function (W₂) from that of the gate electrode 14a.

A preferred mode of implementation of a method for manufacturing the transistor 3 will now be described with reference to FIGS. 6A to 6G. These figures represent, in cross-section views, different steps S1-S7 in the method for manufacturing the transistor 3.

The first step S1, represented by FIG. 6A, consists in forming a gate stack 14′ on a semiconducting layer 30, for example of silicon. The semiconducting layer 30 can be either the active layer of a multilayer structure (typically an SOI substrate) or a bulk semiconductor substrate. The gate stack 14′ comprises the gate electrode 14a and the gate dielectric layer 14b. The gate electrode 14a is herein of a doped semiconductor material, such as doped polycrystalline silicon. The gate dielectric layer 14b is for example of silicon dioxide (SiO₂) or silicon oxynitride (SiON).

Forming the gate stack 14′ may especially comprise depositing a dielectric layer onto the semiconducting layer 30, depositing a layer of doped semiconductor material onto the dielectric layer, etching the layer of doped semiconductor material to delimit the gate electrode 14a and, preferably, etching the dielectric layer through the gate electrode 14a to delimit the gate dielectric layer 14b. As these operations are conventional, they will not be described in greater detail herein.

And then, in step S2 of FIG. 6B, a sacrificial layer 31, preferably of a dielectric material such as SiO₂, is formed at least on flanks of the gate electrode 14a. This sacrificial layer 31 has a thickness e which is preferably between 5 nm and 15 nm.

As illustrated in FIG. 6B, the sacrificial layer 31 is preferentially deposited onto the semiconducting layer 30 (outside the gate stack 14′), the flanks (or lateral surfaces) of the gate electrode 14a and an upper face of the gate electrode 14a. Thus, the sacrificial layer 31 completely covers the gate stack 14′. Deposition is advantageously conformal, that is, the thickness e of the sacrificial layer 31 (measured perpendicularly to the surface on which it rests) is substantially constant.

In S3 (see FIG. 6C), the spacer 17 of the transistor 3 is formed around the gate electrode 14a. The spacer 17 is not in direct contact with the gate electrode 14a, but is separated from the gate electrode 14a by the sacrificial layer 31. The spacer 17 is preferably of a dielectric material, for example silicon nitride (SiN). The dielectric material of the spacer 17 is different from that of the sacrificial layer 31. Its formation may comprise:
a sub-step of conformally depositing a dielectric layer onto the semiconducting layer 30 (outside the gate stack 14′), the flanks of the gate electrode 14a and the upper face of the gate electrode 14a; and
a sub-step of anisotropically etching the dielectric layer, along a preferred etching direction perpendicular to the surface S of the semiconducting layer 30, in order to etch the horizontal parts of the dielectric layer (located on the semiconducting layer 30 and the upper face of the gate electrode 14a) and retain its vertical parts (leaning against the flanks of the gate electrode 14a).

When the sacrificial layer 31 has been deposited onto the semiconducting layer 30, the spacer 17 is further separated from the semiconducting layer 30 by the sacrificial layer 31 (see FIG. 6C).

Anisotropic etching is advantageously selective relative to the sacrificial layer 31 (the sacrificial layer 31 therefore serves as an etching stop layer).

During step S4, represented by FIG. 6D, the sacrificial layer 31 is partially etched so as to expose a part of the flanks of the gate electrode 14a.

This etching step S4 may comprise two successive operations: a first operation of etching the upper portion of the sacrificial layer 31, with a stop on the upper face of the gate electrode 14a, and a second operation of over-etching the sacrificial layer 31, to etch a portion located between the gate electrode 14a and the spacer 17. The portion of the sacrificial layer 31 disposed on the semiconducting layer and not covered by the spacer 17 is etched at the same time as the upper portion, during the first operation.

By way of example, the sacrificial layer 31 is etched anisotropically by means of a fluorocarbon plasma, and then by wet etching in a hydrofluoric acid (HF) bath, with over-etching lower than or equal to 30%. The sacrificial layer 31 can also be etched only by plasma etching.

With reference to FIG. 6E, the manufacturing method may then comprise a step of cleaning the exposed surface of the semiconducting layer 30 (or so-called “free” surface, that is, not covered by the gate stack 14′, the sacrificial layer 31 and the spacer 17), the upper face of the gate electrode 14a and the exposed part of the flanks of the gate electrode 14a. This optional cleaning step is advantageously carried out so as to continue etching the sacrificial layer 31 between the gate electrode 14a and the spacer 17.

Such cleaning is in particular useful when the gate electrode 14a is of polycrystalline silicon. It makes it possible to continue etching the sacrificial layer 31 while limiting the consumption of the gate electrode 14a (and of the semiconducting layer 30, if necessary). Cleaning therefore has etching selectivity (of the sacrificial layer 31 with respect to the gate electrode 14a) greater than etching in the preceding step S4.

Cleaning further enables impurities or contaminants to be removed from the surface of the semiconducting layer 30 and the gate electrode 14a, in preparation for subsequent steps of the method.

Cleaning can be carried out wetly (for example by means of a hydrofluoric acid solution in the case of a sacrificial layer 31 of SiO₂) or drily (for example by means of the Siconi™ method in the case of a sacrificial layer 31 of SiO₂).

The following steps S6 and S7 of FIGS. 6F and 6G relate to forming the lateral gate conductor 14c of the transistor 3. The lateral gate conductor 14c is, in this mode of implementation of the manufacturing method, formed of a compound of semiconductor material and one or more metal elements, and more particularly from a silicide in the case of a polycrystalline silicon gate. Steps S6 and S7 can therefore be described as siliciding steps.

In S6 (see FIG. 6F), a metal layer 32 is deposited at least onto the exposed part of the flanks of the gate electrode 14, and advantageously onto the upper face of the gate electrode 14a and the exposed surface of the semiconducting layer 30. The metal layer 32 is for example of titanium, tantalum, platinum, nickel, cobalt or an alloy of several of these metals. Its thickness is, for example, between 5 nm and 15 nm.

Finally, in S7 (see FIG. 6G), annealing is carried out so as to react the metal with (at least) the doped semiconductor material of the gate electrode 14a and transform (at least) one portion (herein peripheral) of the gate electrode 14a into a lateral gate conductor 14c. The lateral gate conductor 14c extends to the gate dielectric layer 14b, in direct contact with a remaining (central) portion of the gate electrode 14a. The residual portion of the sacrificial layer 31 prevents reaction of the metal with the semiconducting layer 30 between the spacer 17 and the gate electrode 14a.

The metal of the metal layer 32 is selected so that the metal-semiconductor compound of the lateral gate conductor 14c has a work function W₂ different from the work function W₁ of the gate electrode 14a (strictly greater or strictly lower than the work function W₁ according to the type of transistor, pFET or nFET respectively).

After the step S4 of partially etching the sacrificial layer 31, and the cleaning step S5 if necessary, the exposed part of the flanks of the gate electrode 14a extends over a height h₁ such that the lateral gate conductor 14c obtained at the end of step S7 extends to the gate dielectric layer 14b (see FIGS. 6E-6G). According to one exemplary embodiment, it can be provided that the height h₁ of the exposed part of the flanks of the gate electrode 14a is greater than or equal to half the height h₂ of the gate electrode 14a and strictly lower than the height h₍₂₎ of the gate electrode 14a (h₂>h₍₁₎≥h₂/2). This exemplary embodiment depends of course on the experimental conditions but also on the materials implemented (species, deposition, annealing, duration, temperatures, etc.). Any change in one of the experimental conditions or in one of the materials will necessarily involve changes in the heights to be provided to ensure that the lateral gate conductor 14c obtained at the end of step S7 extends to the gate dielectric layer 14b.

When the metal layer 32 has been further deposited in direct contact with the upper face of the gate electrode 14a and regions of the semiconducting layer 30, on either side of the gate stack 14′ and the spacer 17, electrically conductive zones 33 are obtained at the same time as the lateral gate conductor 14c, respectively for making electrical contact of the gate electrode 14a and the source and drain regions 12-13.

A portion of the metal layer 32 may not have reacted during annealing (this is especially the case for the portion of the metal layer 32 disposed on the spacer 17, in the case of a “full plate” deposit). This remaining portion of the metal layer 32 is then removed after annealing.

The manufacturing method also comprises a step of forming the source and drain regions 12-13 in two distinct regions of the semiconducting layer 30, preferably by (ion) implantation of doping impurities, the remaining (non-implanted) portion of the semiconducting layer 30 then forming the channel region 11 of the transistor 3 (this step therefore also makes it possible to delimit the channel region 11).

This step of forming the source and drain regions 12-13 is carried out after the step S3 of forming the spacer 17, preferably before the step S4 of etching the sacrificial layer 31 (ion implantation is therefore performed through the sacrificial layer).

The manufacturing method may also comprise, in the case of a multilayer structure, a step of forming a back gate 15′ under the buried insulating layer 16, preferably by implanting doping impurities (ions) into the support layer of the multilayer structure. This step of forming the back gate 15′ is carried out before the step S1 of forming the gate stack 14′.

As these other manufacturing steps are conventional, they will not be described in more detail.

The manufacturing method described above in relation to FIGS. 6A-6G is particularly simple to implement and comprises fewer technological steps than the method for manufacturing the transistor 2 of FIG. 2. It further enables the simultaneous formation of the lateral gate conductor 14c and the contact-making zones 33, for the gate electrode 14a and the source and drain regions 12-13. The remaining portion of the sacrificial layer 31, when formed of a dielectric material such as SiO₂, helps to decrease the stray capacitances of the transistor 3.

Numerous alternatives and modifications to the manufacturing method will become apparent to those skilled in the art. In particular, the sacrificial layer 31 and the spacer 17 can only be formed against a part of the flanks of the gate electrode, and especially against a single flank, that has to be on the side of the drain region (as a result of which the lateral gate conductor 14c is disposed against this single flank).

1. A method for manufacturing a field effect transistor comprising a source region, a drain region and a channel region disposed between the source and drain regions, the method comprising:
forming a gate stack on a semiconducting layer, the gate stack comprising a gate dielectric layer disposed on the semiconducting layer and a gate electrode separated from the semiconducting layer by the gate dielectric layer, the gate electrode being formed of a doped semiconductor material having a first work function, the gate electrode having a first flank to be on the side of the source region and a second flank to be on the side of the drain region;
forming a sacrificial layer covering at least the second flank of the gate electrode;
forming a spacer against at least the second flank of the gate electrode, the spacer being separated from the gate electrode by the sacrificial layer;
partially etching the sacrificial layer so as to expose a part of the second flank of the gate electrode;
depositing a metal layer at least onto the exposed part of the second flank of the gate electrode;
performing annealing so as to react the metal with the doped semiconductor material of the gate electrode and transform a portion of the gate electrode into a lateral gate conductor extending to the gate dielectric layer in direct contact with a remaining portion of the gate electrode, the metal being selected such that the lateral gate conductor is formed of a second conductive material having a second work function, the second work function being:
strictly greater than the first work function in the case of a p-type transistor;
strictly lower than the first work function in the case of an n-type transistor.

2. The method according to claim 1, wherein the sacrificial layer is deposited onto the semiconducting layer, the flanks of the gate electrode and an upper face of the gate electrode, the spacer being further separated from the semiconducting layer by the sacrificial layer.

3. The method according to claim 2, wherein the step of partially etching the sacrificial layer comprises the following operations of:
etching an upper portion of the sacrificial layer disposed on the upper face of the gate electrode;
performing over-etching of the sacrificial layer so as to etch a portion of the sacrificial layer located between the gate electrode and the spacer.

4. The method according to claim 1, further comprising, before the step of depositing the metal layer, a step of cleaning an exposed surface of the semiconducting layer, an upper face of the gate electrode and the exposed part of the second flank of the gate electrode, the cleaning step being carried out so as to continue etching the sacrificial layer between the gate electrode and the spacer.

5. The method according to claim 1, wherein the metal layer is further deposited onto an upper face of the gate electrode and onto exposed regions of the semiconducting layer located on either side of the gate stack and the spacer.
